(19) United States
(12) Patent Application Publication
(10) Pub. No.: US 2014/0318597 A1
(43) Pub. Date: Oct. 30, 2014

(54) HIGH EFFICIENCY SOLAR DEVICE WITH SENSORS

(71) Applicants: AZAM KHAN, KING WILLIAM, VA (US); BRANDON RAEBURN, KING WILLIAM, VA (US)

(72) Inventors: AZAM KHAN, KING WILLIAM, VA (US); BRANDON RAEBURN, KING WILLIAM, VA (US)

(21) Appl. No.: 14/219,626

(22) Filed: Mar. 19, 2014

Related U.S. Application Data
(60) Provisional application No. 61/839,154, filed on Jun. 25, 2013.
(60) Provisional application No. 61/816,984, filed on Apr. 29, 2013.

(51) Int. Cl. H01L 31/052

(52) U.S. Cl. CPC H01L 31/0522
USPC 136/246

(57) ABSTRACT

Disclosed herein is a solar panel support structure that includes a base, a mounting structure extending from the base, and a frame connected to the mounting structure. The frame is configured to receive a solar panel. The structure further includes a first actuator configured to rotate the frame in a first rotational direction and a second actuator configured to rotate the frame in a second rotational direction. The second rotational direction is perpendicular to the first rotational direction. The structure further includes a light sensor system configured to determine the intensity of light coming from each of a north direction, a south direction, an east direction and a west direction. Finally, the structure includes a controller configured to receive input from the light sensor system and control the first actuator and the second actuator such that the first actuator and the second actuator position the frame such that the frame is at least one of perpendicular and substantially perpendicular to the sun.

### RELATED APPLICATION

The present invention is a non-provisional claiming priority to two commonly owned U.S. Provisional Patent Applications: Ser. No. 61/816,984, filed Apr. 29, 2013, of Raeburn, entitled “High Efficiency Solar Panel with Sensors,” and Ser. No. 61/839,154, filed Jun. 25, 2013, of Raeburn, also entitled “High Efficiency Solar Panel with Sensors,” the disclosures of which are herein incorporated by reference to the extent not inconsistent with the present disclosure.

### FIELD OF TECHNOLOGY

The subject matter disclosed herein relates generally to solar devices. More particularly, the subject matter relates to a high efficiency solar device having sensors to control the direction that a solar array (or solar panel) is facing.

### BACKGROUND

Renewable energy sources are becoming more popular with the rising cost of oil and other non-renewable energy resources. Solar energy is one of these renewable energy sources and has proven desirable to harness in many circumstances. As such, commercial and residential installations including solar panels which harvest energy from the sun are becoming more and more common. These installations are generally installed in the ground such that the solar panels face the sun at a desirable angle to better harvest direct sun rays. However, these installations are generally expensive to install, are permanent and are immobile. Further, due to the moving sun, the solar panels in the installations do not receive direct sunlight at an angle which maximizes energy absorption. Furthermore, these permanent installations are often times too expensive for the average residential consumer.

Thus, a more efficient, mobile, and less costly solar device would be well received in the art.

### SUMMARY

According to a first described aspect, a solar panel support structure comprises: a base; a mounting structure extending from the base; a frame connected to the mounting structure, the frame configured to receive a solar panel; a first actuator configured to rotate the frame in a first rotational direction; a second actuator configured to rotate the frame in a second rotational direction, wherein the second rotational direction is perpendicular to the first rotational direction; a light sensor system configured to determine the intensity of light coming from each of a north direction, a south direction, an east direction and a west direction; and a controller configured to receive input from the light sensor system and control the first actuator and the second actuator such that the first actuator and the second actuator position the frame such that the frame is at least one of perpendicular and substantially perpendicular to the sun.

According to a second described aspect, a solar panel device comprises: a base; a post extending from the base; a frame connected to the post; at least one solar panel attached to the frame; a first actuator configured to rotate the post with respect to the base; a second actuator configured to rotate the frame with respect to the post; a light sensor system including a first sensor located within a first opening facing a north direction, a second sensor located within a second opening facing a south direction, a third sensor located within a third opening facing an east direction, and a fourth sensor located within a fourth opening facing a west direction, wherein the light sensor system is configured to determine the intensity of light coming from each of the north direction, the south direction, the east direction and the west direction; and a controller configured to receive input from the light sensor system and control the first actuator and the second actuator such that the first actuator and the second actuator position the frame such the solar panel faces a direction that receives a maximum amount of light energy.

According to a third described aspect, a method comprises: providing a solar panel support structure including: a base; a mounting structure extending from the base; a frame connected to the mounting structure, the frame configured to receive a solar panel; a first actuator; a second actuator; a light sensor system; and a controller; rotating the frame in a first rotational direction with the first actuator; rotating the frame in a second rotational direction with the second actuator, the second rotational direction being perpendicular to the first rotational direction; determining, by the light sensor system, the intensity of light coming from each of a north direction, a south direction, an east direction, and a west direction; receiving, by the controller, input from the light sensor system information pertaining to the intensity of light coming from the north direction, the south direction, the east direction, and the west direction; controlling, by the controller, the first actuator and the second actuator; and positioning, by the controller, the first actuator, and the second actuator, the frame such that the frame is at least one of perpendicular and substantially perpendicular to the sun.

### BRIEF DESCRIPTION OF THE DRAWINGS

The subject matter which is regarded as the invention is particularly pointed out and distinctly claimed in the claims at the conclusion of the specification. The foregoing and other features and advantages of the invention are apparent from the following detailed description taken in conjunction with the accompanying drawings in which:

FIG. 1 depicts a perspective view of a solar panel device in accordance with one embodiment;

FIG. 2 depicts a perspective view of a solar panel device in accordance with one embodiment;

FIG. 3 depicts a side view of a base and the support structure in accordance with one embodiment

FIG. 4 depicts a top cross sectional view of the base and the support structure, taken at arrows 4-4, in accordance with one embodiment;

FIG. 5 depicts a front cross sectional view of the base and the support structure, taken at arrows 5-5, in accordance with one embodiment;

FIG. 6 depicts a side cross sectional view of the base and the support structure, taken at arrows 6-6, in accordance with one embodiment;

FIG. 7 depicts a perspective view of a light sensor system attachable to a solar panel device in accordance with one embodiment;

FIG. 8 depicts a schematic view of a control system of the solar panel device of FIG. 1 or 2 in accordance with one embodiment;

FIG. 9 depicts a computer system of the solar panel device of FIG. 1 or 2 in accordance with one embodiment;

FIG. 10a depicts a top view of a light sensor system in accordance with one embodiment;

FIG. 10b depicts a side cutaway view of the light sensor system of FIG. 10a FIG. 10a taken at arrows 10b;

FIG. 10c depicts a side cutaway view of the light sensor system of FIG. 10a FIG. 10a taken at arrows 10c; and

FIG. 10d depicts a bottom view of the light sensor system of FIG. 10a.

### DETAILED DESCRIPTION

A detailed description of the hereinafter described embodiments of the disclosed apparatus and method are presented herein by way of exemplification and not limitation with reference to the Figures.

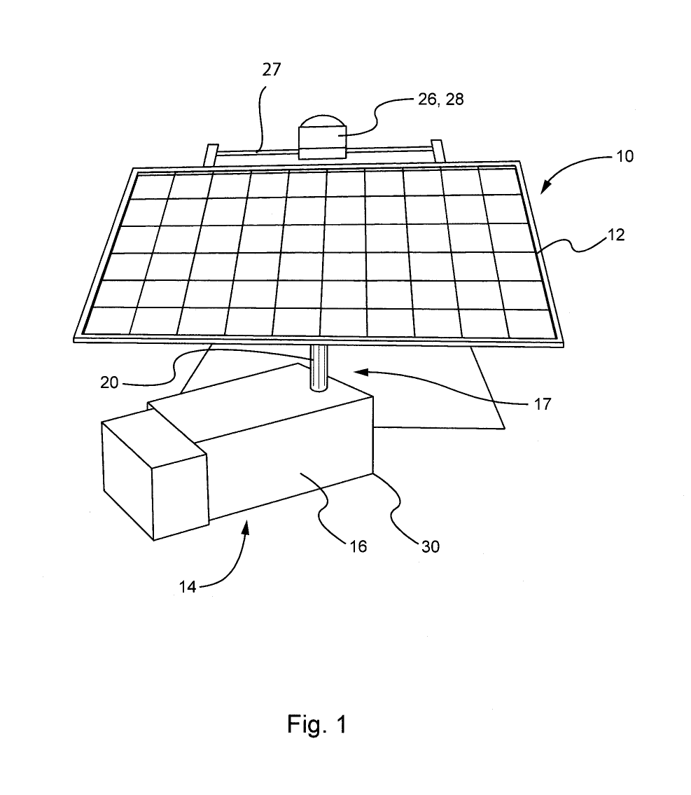

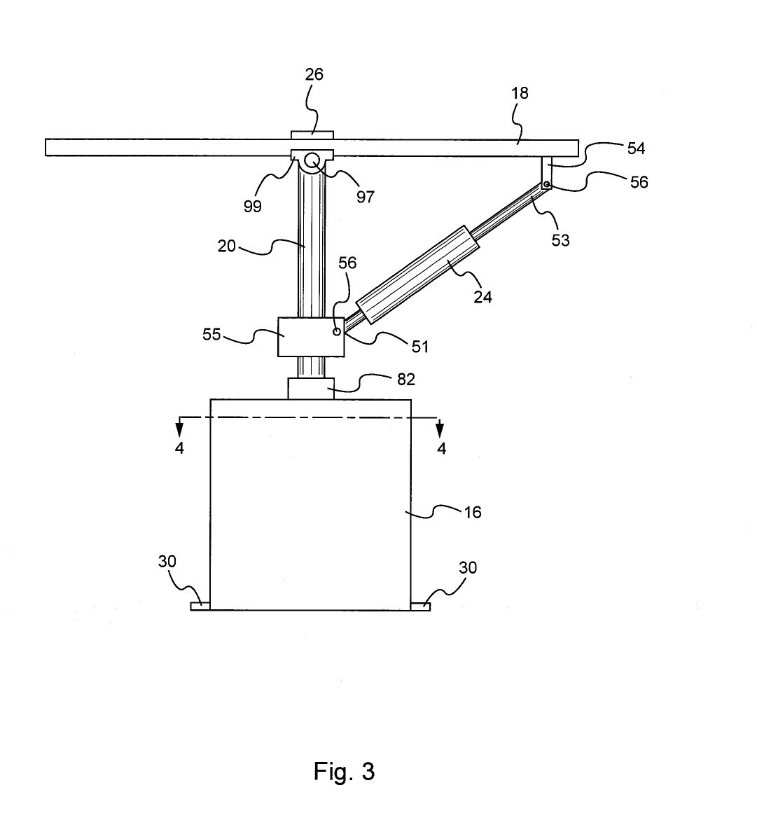

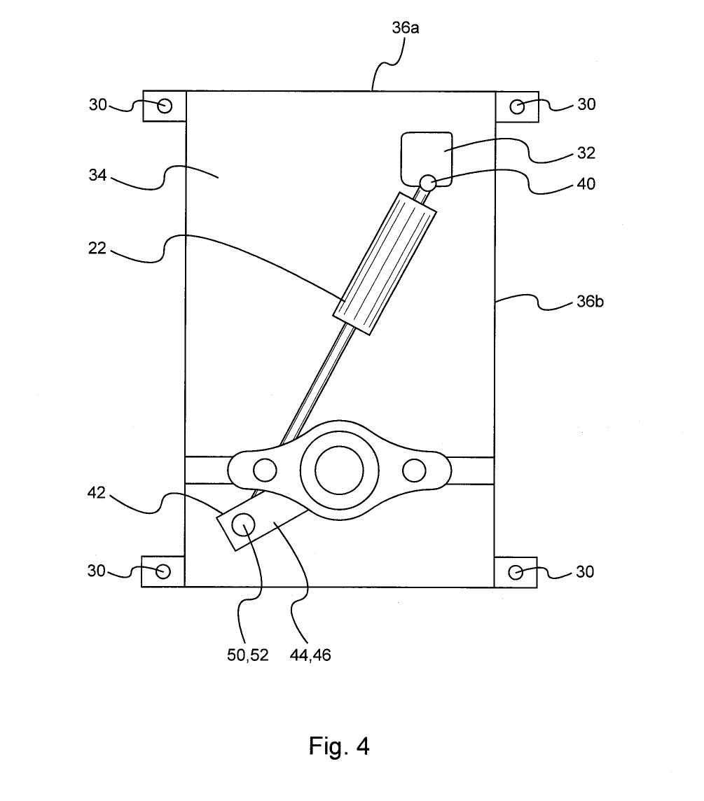

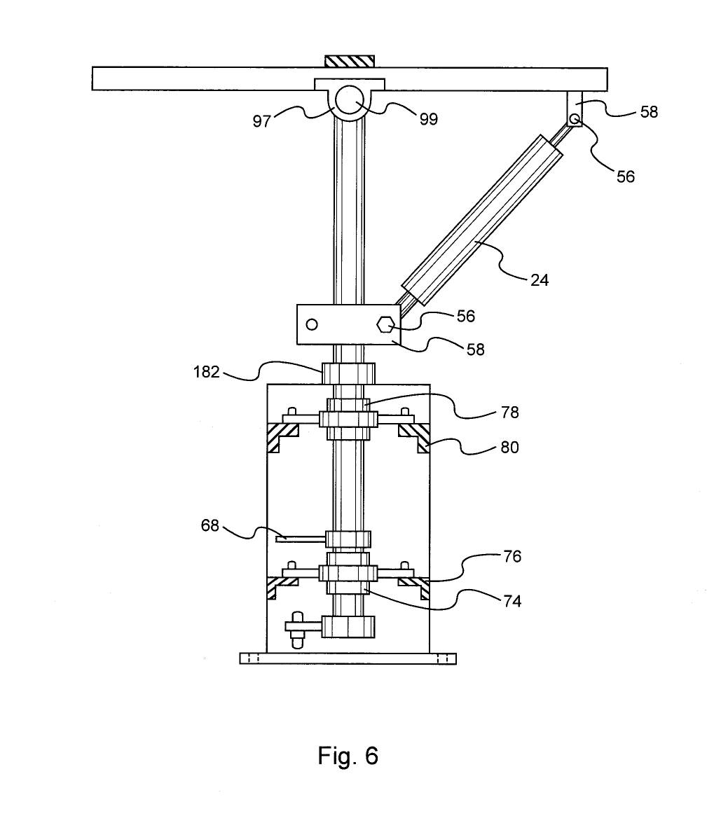

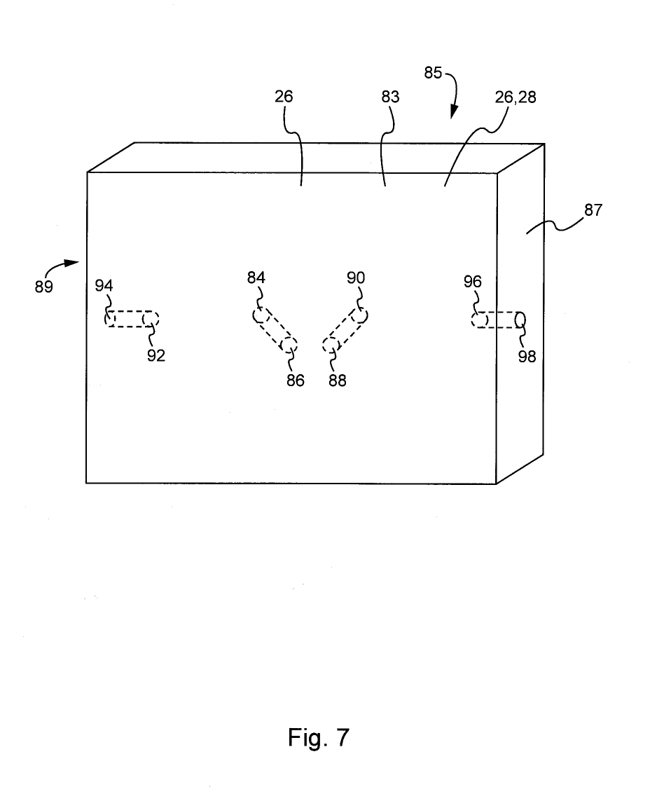

Referring firstly to FIG. 1, a perspective view of a solar panel device 10 is shown having a single solar panel 12. The solar panel device 10 includes a solar panel support structure 14 which may include each of the structural elements of the solar panel device 10 with the exception of the solar panel 12. The solar panel device 10 and the solar panel support structure 14 may include a base 16, and a mounting structure 17 which extends from the base 16. A frame 18 may be connected to the mounting structure 17 which is configured to receive the solar panel 12. The frame 18 may be a fixed frame or may be collapsible for storage and transportation of the solar panel device 10. The mounting structure 17 may particularly include a post 20 extending from the base 16. In one embodiment, the post 20 may be telescopic in nature and may include its own hydraulic system for increasing or decreasing its height in order to avoid shadows caused by near-ground objects. The solar panel device 10 may include a first actuator 22 (shown in FIGS. 4 and 6) and a second actuator 24 (shown in FIGS. 3, 5 and 6). The first actuator 22 may be located within the base 16 and may be configured to rotate the post 20 with respect to the base 16 and thereby rotate the frame 18 in a first rotational direction D1. The second actuator 24 may be configured to rotate the frame 18 with respect to the post 20, and thereby rotate the frame 18 in a second rotational direction D2 which is perpendicular to the first rotational direction D1. The solar panel device 10 may further include a light sensor system 26 (shown particularly in FIG. 7). The light sensor system 26 may be configured to determine the intensity of light coming from each of a north direction, a south direction, an east direction, and a west direction. Additionally, the solar panel device 10 may include a controller 28 configured to receive input from the light sensor system 26 and control the first actuator 22 and the second actuator 24 such that the first actuator 22 and the second actuator 24 position the frame 18 such that the frame 18 is perpendicular or substantially perpendicular to the sun. Thus, the solar panel device 10 may be configured to maximize the absorption of sunlight absorbed by the solar panel 12 resting on the frame 18.

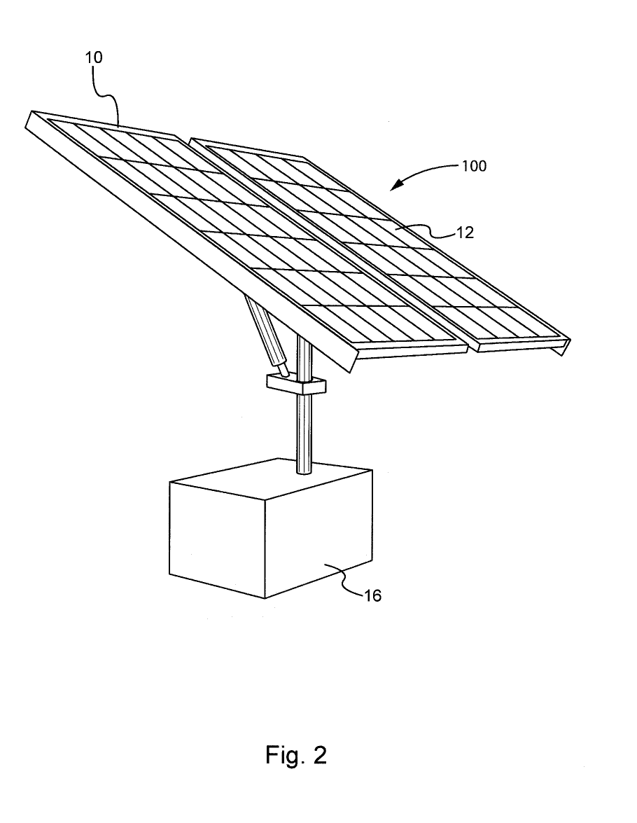

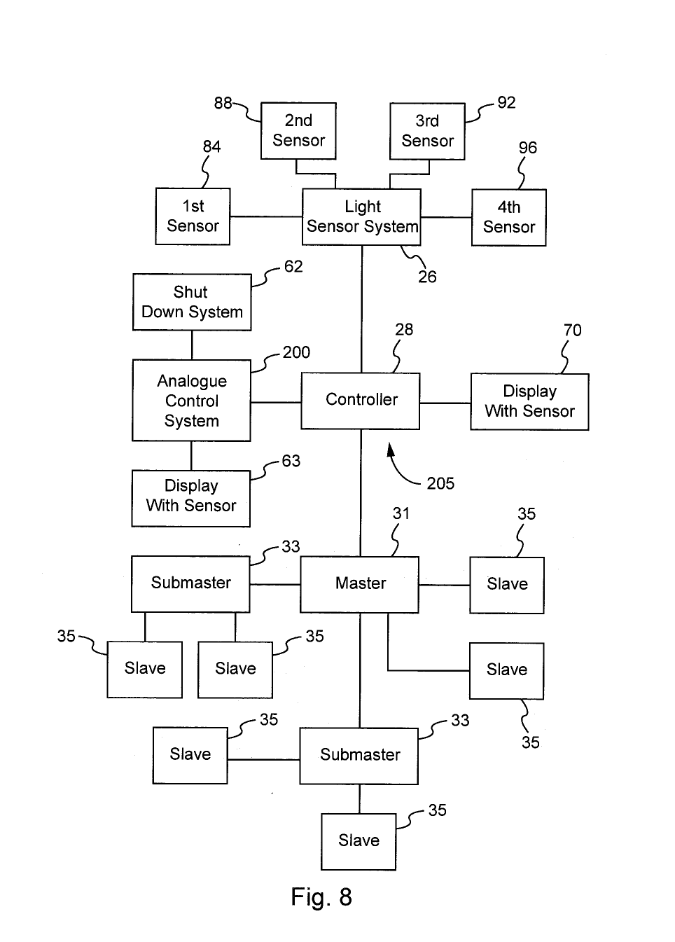

The solar panel device 10 is shown to include a single large solar panel 12. However, it should be understood that the principles described herein may be applicable to a solar panel device 10 which includes a plurality of solar panels 12, such as the solar panel device 100 shown in FIG. 2 which includes two smaller solar panels 12. Whatever the embodiment, the light sensor system 26 and controller 28 combination may be configured to control one or more frames upon which any number of solar panels (i.e. from one panel to a large array) are installed. Additionally, the light sensor system 26 and controller 28 combination may be configured to control the movement of a plurality of solar panel devices, each device similar to the solar panel device 10. Thus, a system is contemplated in which a single solar panel device, such as the solar panel device 10 is a master device 31 and includes a controller and light sensor system, such as the controller 28 and light sensor system 26, which controls the movement of a number of slave solar panel devices 35 (shown in FIG. 8), the slave solar panel devices 35 thereby not being required to include their own individual controller or light sensor system. The master 31 and slave 35 solar panel devices may be in communication via a wired or wireless connection. In one embodiment, each of the slave devices 35 may include their own light sensor system and controller, but the slave light sensor systems and controllers may be powered off during normal operation, and only utilized as backup systems in the event that the master 31 system experiences a problem. In yet another embodiment, a single master system 31 may control a number of sub-master systems 33, each sub master system 33 controlling portions of each slave system 35.

Referring now to FIG. 3, a side view of the solar panel support structure 14 including the base 16 and the mounting structure 17 of the solar panel device 10 is shown. The base 16 may be a large six sided box structure. However, the base 16 may be of any shape (rectangular or irregular). For example, the top view of the base 16 may a square, square with rounded edges, circle, rectangular, rectangular with rounded edges, squircle, truncated circle, ellipse, oval polygon, etc. The size of the base 16 may vary depending on the size of the frame 18 and the solar panel 12 to be mounted thereon. The base 16 and its contents may provide enough weight to the overall solar panel device 10 to hold down the solar panel device 10 without the need to mount the base 16 with any elongated poles, posts or columns extending into the ground. In one embodiment, however, the base 16 may include a plurality of tie down flanges 30, each tie down flange 30 extending from a corner of the base 16. The tie down flanges 30 may each include an opening through which a nail, bolt, screw, or other hold down device may be inserted. The tie down flanges 30, in combination with the nail, bolt, screw, or other device, may be configured to tie down the solar panel device 10 to a concrete, wood, plastic, or other hard surface such as a surface found on a roof of a building or a paved surface. Thus, no permanent construction may be required to set up the solar panel device 10 disclosed herein. However, in some embodiments a column, pole, post, or the like may extend from the base 16 in order to more permanently install the solar panel device 10 in a softer ground surface such as soil, dirt, grass or the like.

Shown in FIGS. 4-6 are the internal components of the solar panel device 10, which are particularly shown in more detail with cutaway views. Referring first to FIG. 4, a top cutaway view from within the base 16 is shown. Shown in particular detail in this view is the first actuator 22. The first actuator 22 is mounted to a corner inside the base 16 with a first actuator mount 32. The first actuator mount 32 may be mounted to either a bottom surface 34 of the base 16 or to a side surface 36a, 36b of the base 16. The actuator mount 32 may be configured to hold a first end 40 of the first actuator 22 at a stable first location. The first end 40 of the first actuator 22 may be pivotally connected to the actuator mount 32. Thus, the first actuator 22 may have one degree of rotational freedom at the first end 40. In other embodiments, the first actuator 22 may be connected at the first end 40 at the actuator mount 32 with a ball joint or a joint with more than one degree of rotational freedom.

The first actuator 22 may be attached to the post 20 at a second end 42. The first actuator 22 may be attached to the post 20 at the bottom of the post 20. Alternately, the first actuator 22 may be attached to a mid-point of the post 20 if the first actuator 22 is located above the bottom surface of the base 16. The first actuator 22 may be attached to the post 20 at a post-surrounding plate 44. The post-surrounding plate 44 may be attached to the post 20 such that rotation of the post-surrounding plate 44 exacts rotation on the post 20. The post-surrounding plate 44 is shown to include at least one extended portion 46. The extended portion may include an opening 48 which corresponds to an opening 50 found in the second end 42 of the first actuator 22. A bolt 52 or other connecting interface may extend through both the opening 50 in the second end 42 of the first actuator 22 and the opening 48 in the post-surrounding plate 44. Thus, the first actuator 22 may have one rotational degree of freedom at the second end 42.

The first actuator 22 may include a hydraulic system to allow for the first actuator 22 to expand or contract. Thus, the first actuator 22 may be telescopic in nature. Expansion and contraction of the first actuator 22 may be controlled by the controller 28. The first actuator 22 may thereby be expanded in order to exact counterclockwise rotation in a direction R1, as shown in FIG. 4. Likewise, contraction of the first actuator 22 may thereby exact clockwise rotation in a direction R2, as shown in FIG. 4. The amount of rotation possible using first actuator 22 shown in the Figures may be close to 180 degrees. However, to prevent a full rotation, the first actuator 22 may be prevented from allowing the difference between the two maximum rotation points to approach too closely to the 180 degrees. Thus, the post 20 may be configured to rotate up to 170 degrees, for example, by the maximum expansion and maximum contraction of the first actuator 22.

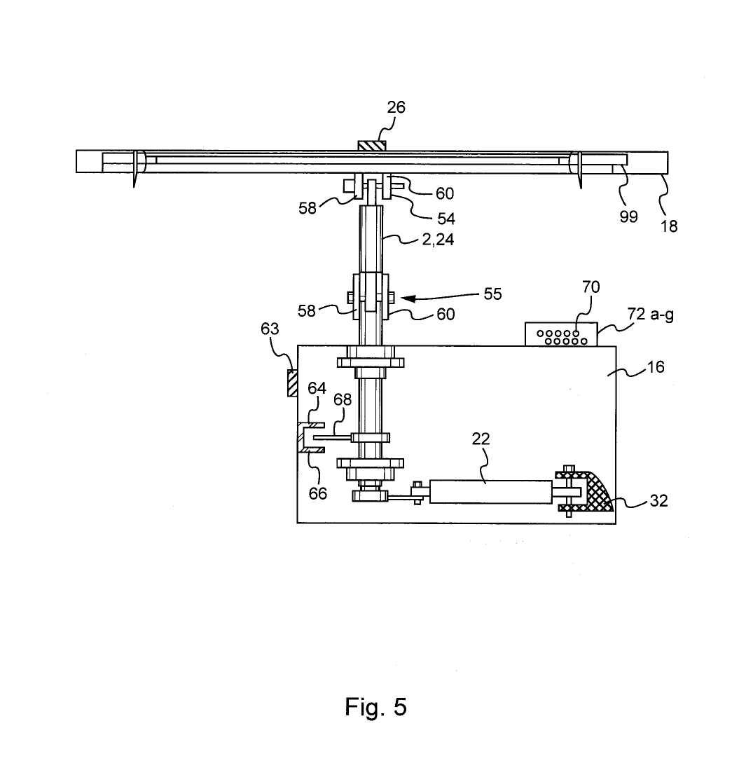

Referring now to FIG. 5, the second actuator 24 is more clearly shown. The second actuator may extend from a first end 51 to a second end 53. The first end 51 may be attached to or operably attached to the post 20, while the second end 53 may be attached to or operatively attached to the frame 18 at or proximate a top or bottom edge. In the case that the second actuator 24 is attached at or proximate the bottom edge of the frame 18, for example, the dimensions of the second actuator 24 may be minimized in order to reduce cost of the part. Wherever the second actuator 24 is attached, the second actuator 24 may include a hydraulic system to allow for the second actuator 24 to expand or contract. Thus, the second actuator 24 may be telescopic in nature. Like the first actuator 22, expansion and contraction of the second actuator 24 may be controlled by the controller 28. The second actuator 24 may thus expand, for example, in order to move the bottom edge of the frame 18 upward with respect to the base 16 and consequently also move the top edge of the frame 18 downward with respect to the base 16. Thus, the second actuator 24 may be configured to rotate the frame in the second rotational direction D2, which may be perpendicular to the first rotational direction D1 caused by the first actuator 22. In other words, the first rotational direction D1 may create an angular velocity vector which is located in a first direction which is parallel to the post 20, for example. The second rotational direction D2 may create an angular velocity vector which is located in a second direction which is perpendicular to the post 20, for example. It should be understood that this is what is meant by perpendicular rotational directions. Furthermore, it should be understood that “perpendicular rotational directions” herein means “substantially perpendicular” to the extent that a small amount of divergence (i.e. 5 degrees or less) from true ninety degree perpendicularity would be considered a “perpendicular rotational direction” within the meaning of the phrase in the present disclosure.

The second actuator 24 may be connected by, and extend between, a post coupling 55 and a frame coupling 54. The post coupling 55 and the frame coupling 54 can each be seen in FIGS. 3 and 6. In one embodiment, the first end 51 and the second end 53 may each include an eye opening for insertion of a connecting apparatus 56 which may be a bolt, pin, screw, or the like. The connecting post coupling 55 and the frame coupling 54 may each include a left wall 58 and a right wall 60 defining a channel within which the eye opening of the first end 51 and the second end 53 reside. Like the eye openings, the left and right walls 58, 60 may each include openings for receiving the connecting apparatus 56. Thus, the second actuator 24 may be pivotally attached at both the first end 51 and the second end 53. The second actuator 24 may thus have one rotational degree of freedom about the first end 51 and one rotational degree of freedom about the second end 53. It should be understood that the couplings 54, 55 described hereinabove are not limiting and that any attachment mechanism for attaching the second actuator 24 to the post 20 and the frame 18 is within the purview of the present disclosure.

As shown in FIG. 6, a shutdown sensor 62 is shown within the base 16. The shutdown sensor 62 is attached to a side wall or surface 36a of the base 16. The shutdown sensor 62 may be in operable communication with, or may comprise, an analogue control system 200. The analogue control system 200 and/or shutdown sensor 62 may include an upper protruding plane 64 having a light emitting diode (LED) disposed thereon, and a lower protruding plane 66 having a light dependent resistor (LDR) disposed thereon. The LED may be configured to direct light at the LDR. This light direction may be constant or may occur at regular and predictable intervals. The analogue control system 200 further may include a blade 68 attached to the post 20 such that the blade 68 rotates along with, and the same amount as the post 20. The blade 68 may pass within or between the upper protruding plane 64 and the lower protruding plane 66 such that the blade 68 may be configured to block the light from the LED from reaching the LDR when post 20 has been rotated to a predetermined position that corresponds to an end of daylight in a given day. Thus, the shutdown sensor 62 may be positioned within the base 16 such that the rotation of the frame 18 is rotated in a westward direction when the blade 68 blocks the shutdown sensor 62. It should be understood that the blade 68 may be considered a projection, a pin, a surface, a link, or any other element which can be attachable to or rotatable with the post 20. Furthermore, the blade 68 may be an integral component of the post 20, or welded thereon, in one embodiment.

It should further be understood that other embodiments are contemplated besides the analogue control system 200 and/or shutdown sensor 62. For example, the controller 28 may further be capable of sensing and controlling the on/off condition of the solar panel device 10. The key capability of the analogue control system 200 and/or shutdown sensor 62 may be to determine the day/night condition and return post 20 to a rotational home position at night, such that the frame 18 is perpendicular to an eastward direction to await the morning day condition. Furthermore, the analogue control system and/or shutdown sensor 62 may be configured to prevent stray light sources, such as the headlights of an automobile, from being construed as a day condition. In other words, the analogue control system 200 and/or shutdown sensor 62 may be equipped to automatically shut down the solar panel device 10 for a number of hours once the night condition is determined to exist, even if lights continue to be sensed by the light sensor system 26.

The analogue control system 200 may further include a second sensor 63 located outside of the base 16. The second sensor 63 may be configured to detect morning and evening by sensing the conditions such as the amount of light in the various directions, the time of day, the direction (north, east, south and west) the light is coming from and the amount of time the light has been exposed (i.e. a light having a short duration may be determined to not be emitted from a constant light source such as the sun). The second sensor 63 may contain two photo cells, namely two LDR's, and an LED. There may be a barrier wall between the first and second LDR's. The first LDR may be configured to detect a dusk condition, and the second LDR may be configured to detect a dawn condition. The LED may create an artificial day condition detectable by the LDR during the transition to a home position after the blade 68 has reached the position to block the shutdown sensor 62. In another embodiment, the second sensor 63 may contain three LDR's, two LED's. The three LDR's and npn phototransistor may work in combination to detect the dusk and dawn conditions. The two LED's may work in combination to create an artificial day condition detectable by the LDR's during the transition to a home position after the blade 68 has reached the position to block the shutdown sensor 62. In other embodiments, more or less LDR's, LED's, and npn phototransistors may be utilized in order to detect morning and evening in a similar manner as that which has been described hereinabove.

Referring still to FIGS. 5 and 6, the post may be held in place within the base 16 with a first bearing 74 and bearing mount 76 and a second bearing 78 and bearing mount 80. The first bearing 74 and bearing mount 76 may be located below the blade 68 and analogue control system and/or sensor 66. The second bearing 78 and bearing mount 80 may be above the blade 68 and the analogue control system and/or sensor 66. The bearing mounts 76, 80 may each be mounted to opposing internal surfaces or sides of the base 16. The bearing mounts 76, 80 and bearings 74, 78 may each be configured to retain the post 18 to remain in the same position but enable the post 18 to rotate. The bearing mounts 76, 80 may be plates which have sufficient mechanical strength to ensure that the post 18 is held into place.

Still further, the post may extend through the top surface or side of the base 16 through an opening in the base 16. A cap 82 or ring seal device may be provided above the opening where the post 18 extends through the base 16 in order to seal and protect the internal components of the base 16 from rain and other elements. However, it should be understood that the base 16 may include a removable panel, door, or other device that may provide access to the internal components of the base 16 for maintenance and repair purposes.

The post 18 may further be connected to a horizontal shaft 99 with a bearing 97. The horizontal shaft 99 may be a component of the frame 18 such that rotation of the horizontal shaft 99 about the bearing 97 provides for rotation of the frame 18 about the post 20 and the base 16 in the second rotational direction D2. Thus, the frame 18 may have one degree of rotational freedom about the post 20 via the bearing 97.

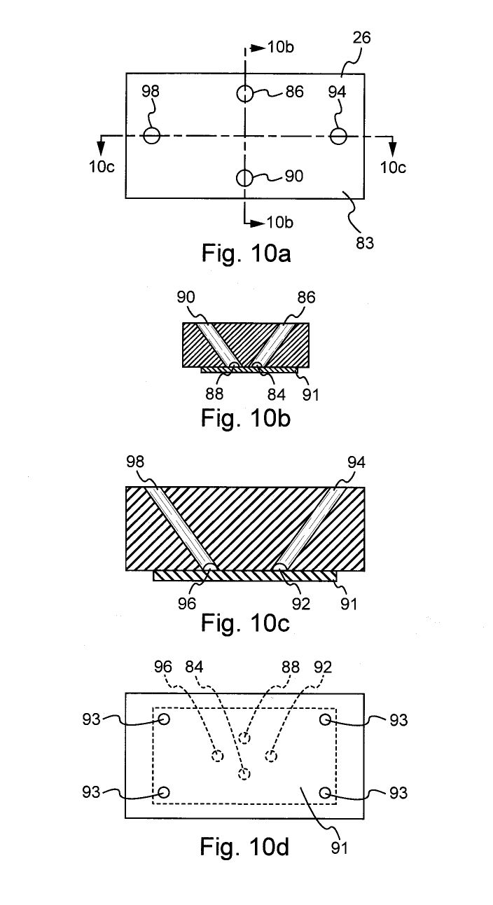

Referring now to FIG. 7, the light sensor system 26 is shown attached proximate a top edge of the frame 18. In the embodiment shown in FIG. 1, for example, the light sensor system 26 is attached to a mounting device 27. The mounting device 27 may include a left side and a right side mount and post extending therebetween. In other embodiments, it should be understood that the light sensor system 26 may be attached or proximate to the bottom edge, right edge, left edge or even a center or middle point on the solar panel device. The light sensor system 26 may be attached anywhere near the frame 18 such that the light sensor system 26 moves with the frame 18. The light sensor system 26 may include a surface 83 which is oriented parallel to the plane defined by the outer edges of the frame 18. The light sensor system 26 may include a first sensor 84 located within a first opening 86, a second sensor 88 located within a second opening 90, a third sensor 92 located within a third opening 94, and a fourth sensor 96 located within a fourth opening 98. The first opening 86 may be configured to face and extend into a first direction S1, the second opening 90 may be configured to face and extend into a second direction S2, the third opening 94 may be configured to face and extend into a third direction S3, and the fourth opening 98 may be configured to face and extend into a fourth direction S4. The first direction S1 may point generally northward, for example. In this instance, the second direction S2 may point generally southward, while the third direction S3 may point generally eastward and the fourth direction S4 may point generally westward. These directions may be arbitrary to the extent that movement of the base 16 of the solar panel device 10 may move the openings and the directions in which they face. In the embodiment shown in FIG. 7, the openings point in perpendicular directions. For example, the first direction S1 may point in a direction that is 90 degrees from the third direction S3 and the fourth direction S4. In other embodiments, shown in FIGS. 10a-10d, the openings may be directed in other manners, described hereinbelow.

Each of the first, second, third and fourth openings 86, 90, 94, 98 may extend into the surface 83 of the light sensor system 26, as shown in FIGS. 10a-10d. Alternately, as shown in the embodiment in FIG. 7, only the first opening 86 may extend into the surface 83. The second opening may extend into a surface 85 located on an opposite side of the box 26 to the surface 83. The third and fourth openings 94, 98 may extend from opposite sides 87, 89 that are located between the first and second surface 83, 85. Whatever the embodiment, the first, second, third and fourth sensors 84, 88, 92, 96 may each be npn phototransistors. In other embodiments, the first, second, third and fourth sensors 84, 88, 92, 96 may each be LEDs, other photo sensors, or combinations thereof. In operation, depending on the amount of light being sensed by each of the sensors 84, 88, 92, 96, the sensor is configured to provide varying degrees of a current response to the controller 28 to interpret. However, other types of sensors may be utilized besides npn phototransistor sensors. Further, the controller 28 may be located within the housing of the light sensor system 26. Alternately, the controller 28 may be located within the housing of the base 16. Whatever the embodiment, the controller 28 may be in operable communication with the sensors 84, 88, 92, 96 with either a wired or wireless connection such that the sensors 84, 88, 92, 96 are configured to provide data for the controller to interpret.

While the light sensor system 26 is shown in FIG. 7 to include a single box with four sensors 84, 88, 92, 96 and openings 86, 90, 94, 98, other embodiments are contemplated. For example, the light sensor system 26 may include a plurality of boxes. For example, it is contemplated that four boxes may be provided, each including its own opening and accompanying sensor. Alternately, two boxes may each include two sensor and opening combinations.

Thus, when sun is perpendicular to the sensor plane, each of the four openings 86, 90, 94, 98 receives equal amount of light. As a result, each of the four corresponding npn phototransistor sensors 84, 88, 92, 96 allow passage of equal amounts of current. When sun is not perpendicular to the sensor plane, for the east-west pair of openings 94, 98, the third opening 94 receives more amount of light than the fourth opening 98 or vice versa. Similarly, for the north-south pair of openings 86, 90, the first opening 86 receives more amount of light than the second opening 90 or vice versa.

The sensors 84, 88, 92, 96 may work as follows. If the first sensor 84 within the first oriented opening 86 experiences more light than the second sensor 88 within the second oriented opening 90, the sensors 84, 88 may send a logic signal to the controller 28 in order to activate expansion of the second actuator 24 (assuming the second actuator 24 is attached to a bottom edge of the frame 18). Likewise, if the sensor 88 within the second oriented opening 90 experiences more light than the sensor 84 within the first oriented opening 86, the sensors 84, 88 may send a logic signal to the controller 28 in order to activate contraction of the second actuator 24 (again, assuming the second actuator 24 is attached to a bottom edge of the frame 18).

Similarly, if the sensor 92 within the third oriented opening 94 experiences more light than the sensor 96 within the fourth oriented opening 98, the sensors 92, 96 may send a logic signal to the controller 28 in order to activate expansion of the first actuator 22 to cause the post to rotate in the counter clockwise direction R1. Likewise, if the sensor 96 within the fourth oriented opening 98 experiences more light than the sensor 92 within the third oriented opening 94, the sensors 92, 96 may send a logic signal to the controller 28 in order to activate contraction of the first actuator 24 to cause the post to rotate in the clockwise direction R2.

As shown in FIGS. 10a-10d, another embodiment of a light sensor system 26 is shown. In this embodiment, the openings are not completely oriented perpendicular from each other. In this embodiment, the first and second openings 86, 90 may each extend in a direction that converges at a location that is located Ll that is equidistant from each of the first and second openings 86, 90 and which is located behind the back of the housing of the light sensor system. The direction in which the first opening 86 and the second opening 90 extends may be each from a bottom 85 and up through the surface 83 of the housing of the light sensor system 26. The locations of the sensors 84, 88, 92, 96 are shown in the bottom view of FIG. 10d. Thus, the sensors 84, 88, 92, 96 may be located closer to a middle point on the bottom 85 of the housing of the light sensor system 26 and the openings 86, 90, 94, 98 may extend from this middle point to an outer location of the housing on the surface 83 of the housing of the light sensor system 26. The angles at which these openings extend with respect to the bottom surface 85 of the housing may be between 33 and 67 degrees or even zero (0) to 90 degrees. In other embodiments, the angles may be greater than 90 degrees. In other embodiments, the angle may be any angle which may detect light. In one embodiment, as shown, the first and second openings 86, 90 may extend at a larger (or steeper) angle with respect to the bottom surface 85 of the housing than the third and fourth openings 94, 98. Still further a printed circuit board 91 may be included on the bottom surface 85 of the housing which connects the four sensors 84, 88, 92, 96. This printed circuit board may be attached to the bottom surface 85 of the housing with bolts or screws 93. The printed circuit board may include a transmitter and/or a receiver and may be in communication with the controller 28. Still further, in the embodiment where each of the sensor and openings is found in a separate housing, the separate housing may include its own communicative printed circuit board system in the same manner as shown in FIG. 10d.

Still further, the solar panel device 10 may include a display system 70 or system which may include a status LED 72a, 72b, 72c, 72d for each of the four directions, east, west, north, south. The status LEDs 72a, 72b, 72c, 72d in combination may convey to a user which direction the frame 18 and solar panel 12 are moving. This may facilitate use due to the slow movement of the actuators 22, 24 may be difficult for the eye to notice. For example, if the east LED 72a is blinking, the light sensor system 26 may indicate that the frame 18 and solar panel 12 may be moving in the east direction. In one embodiment, if both the east LED 72a and west LED 72b are blinking, the first actuator 22 may be off. Similarly, if north LED 72c and south LED 72d are both blinking, the second actuator 24 may be off. The display system 10 may further include additional LEDs 72e, 72f, 72g, 72h configured to display at least one of an overcharge protection state, low battery voltage, a charging state, a discharging state, and a power save mode being activated. The display interface 70 may further include an input system to allow a person or user to manually input certain instructions to the controller 28, such as manually turning the movement of the system on or off.

Referring now to FIG. 8, a schematic view of a control system 205 of the solar panel device 10. The control system 205 may include the controller 28. The controller may be in signal communication with the light sensor system 26, as described hereinabove. The light sensor system is shown in the schematic to include each of the first sensor 84, the second sensor 88, the third sensor 92 and the fourth sensor 96. The controller is further in electrical or signal communication with the analogue control system 200 which comprises the shut down sensor 62 and the day/night sensor 63. The controller 28 is likewise in communication with a display interface 70. The controller 28 is also shown connected to a master system 31. The master 31 may include each of the elements 26, 28, 62, 63, 70, 84, 88, 92, 96, 200 shown that the master 31 is connected to. Additionally, the master system 31 may be connected to a number of slave systems 35, or sub master systems 33. The sub master systems 33 may be connected to a number of slave systems 35, as described hereinabove. It should be understood that many slaves may be found directly connected to a single master, rather than only one as shown. Further, multiple slaves may be found directly connected to each sub-master, rather than only two as shown. Still further, multiple sub-masters may be found under the control of a single master system, rather than only two as shown.

In still another embodiment, a method is contemplated. The method may include providing a solar panel support structure or solar panel device, such as the support structure 14 or the solar panel device 10. The structure or device may include a base, such as the base 16, a mounting structure extending from the base, such as the mounting structure 17, a frame connected to the mounting structure, such as the frame 18, a first actuator, such as the first actuator 22, a second actuator, such as the second actuator 24, a light sensor system, such as the light sensor system 26, and a controller, such as the controller 28. The method may include rotating the frame in a first rotational direction with the first actuator. The method may further include rotating the frame in a second rotational direction with the second actuator, the second rotational direction being perpendicular to the first rotational direction. The method may further include determining, by the light sensor system, the intensity of light coming from each of a north direction, a south direction, an east direction, and a west direction. Still further, the method may include receiving, by the controller, input from the light sensor system information pertaining to the intensity of light coming from the north direction, the south direction, the east direction, and the west direction. The method may include controlling, by the controller, the first actuator and the second actuator. The method may further include positioning, by the controller, the first actuator, and the second actuator, the frame such that the frame is at least one of perpendicular and substantially perpendicular to the sun.

Still further, the method may include detecting with an analogue control system, such as the analogue control system 200, a day and a night state. The method may include communicating the day and night state from the analogue control system 200 to a controller, such as the controller 28 whether the solar panel support structure resides in the day state or the night state. The method may further include displaying, on a display screen, whether the device is in at least one of an overcharge protection state, low battery voltage, a charging state, a discharging state, and a power save mode. The method may include rotating a blade, such as the blade 68, to block light from an LED directed at an LDR, where the blockage is configured to occur substantially (i.e. a number of minutes) within the end of daylight in a given day. The method may further include hydraulically activating the first and second actuators with the controller. The method may further include rotating the post with the first actuator when the first actuator is expanded or contracted, and rotating the frame with respect to the post by the second actuator when the second actuator is actuated.

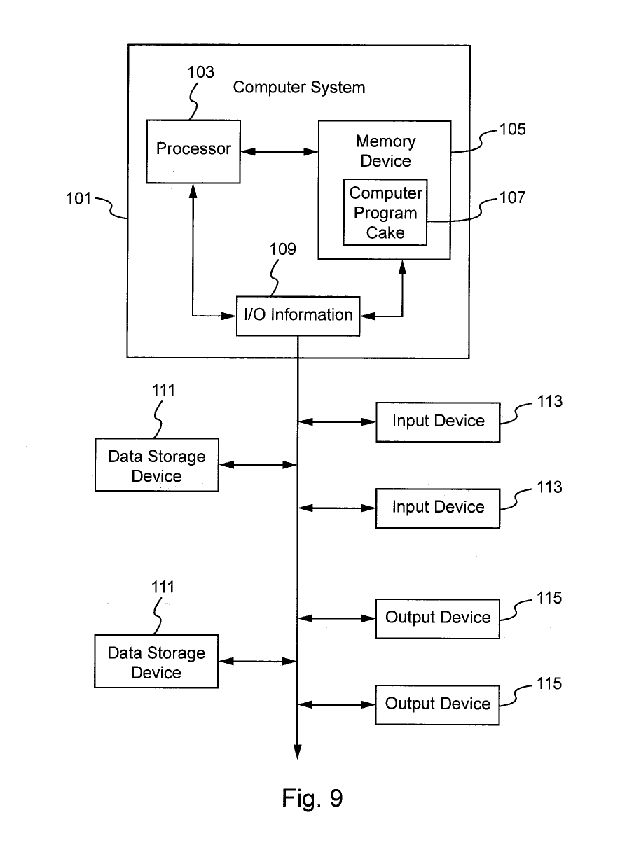

It should be understood that any or all of the steps or functions of the controller 28 or the analogue controller 200 taught in the present disclosure of the methods for moving the solar panel device 10 described herein may be performable, for example, by a computer system 101 shown in FIG. 9. It should be understood that the computer system 101 shown in FIG. 9 may represent one or both of the controller 28 or the analogue controller 200 or any other processing device described herein with respect to the solar panel device 10. In particular, FIG. 9 shows the structure of a computer system and computer program code that may be used to implement the functionality described herein of the controller 28 or the analogue controller 200 or any other functionality described herein of the solar panel device 10. FIG. 9 refers to objects 101-115.

Aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module,” or “system.” Furthermore, in one embodiment, the present invention may take the form of a computer program product comprising one or more physically tangible (e.g., hardware) computer-readable medium(s) or devices having computer-readable program code stored therein, said program code configured to be executed by a processor of a computer system to implement the methods of the present invention. In one embodiment, the physically tangible computer readable medium(s) and/or device(s) (e.g., hardware media and/or devices) that store said program code, said program code implementing methods of the present invention, do not comprise a signal generally, or a transitory signal in particular.

Any combination of one or more computer-readable medium(s) or devices may be used. The computer-readable medium may be a computer-readable signal medium or a computer-readable storage medium. The computer-readable storage medium may be, for example, but is not limited to, an electronic, magnetic, optical, electromagnetic, infrared, or semiconductor system, apparatus, or device, or any suitable combination of the foregoing. More specific examples (a non-exhaustive list) of the computer-readable storage medium or device may include the following: an electrical connection, a portable computer diskette, a hard disk, a random access memory (RAM), a read-only memory (ROM), an erasable programmable read-only memory (EPROM or flash memory), Radio Frequency Identification tag, a portable compact disc read-only memory (CD-ROM), an optical storage device, a magnetic storage device, or any suitable combination of the foregoing. In the context of this document, a computer-readable storage medium may be any physically tangible medium or hardware device that can contain or store a program for use by or in connection with an instruction execution system, apparatus, or device.

A computer-readable signal medium may include a propagated data signal with computer-readable program code embodied therein, for example, a broadcast radio signal or digital data traveling through an Ethernet cable. Such a propagated signal may take any of a variety of forms, including, but not limited to, electro-magnetic signals, optical pulses, modulation of a carrier signal, or any combination thereof.

Program code embodied on a computer-readable medium may be transmitted using any appropriate medium, including but not limited to wireless communications media, optical fiber cable, electrically conductive cable, radio-frequency or infrared electromagnetic transmission, etc., or any suitable combination of the foregoing.

Computer program code for carrying out operations for aspects of the present invention may be written in any combination of one or more programming languages, including, but not limited to programming languages like Java, Smalltalk, and C++, and one or more scripting languages, including, but not limited to, scripting languages like JavaScript, Perl, and PHP. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN), a wide area network (WAN), an intranet, an extranet, or an enterprise network that may comprise combinations of LANs, WANs, intranets, and extranets, or the connection may be made to an external computer (for example, through the Internet using an Internet Service Provider).

These computer program instructions may also be stored in a computer-readable medium that can direct a computer, other programmable data-processing apparatus, or other devices to function in a particular manner, such that the instructions stored in the computer-readable medium produce an article of manufacture, including instructions that implement the function/act specified in the flowchart and/or block diagram block or blocks.

The computer program instructions may also be loaded onto a computer, other programmable data-processing apparatus, or other devices to cause a series of operational steps to be performed on the computer, other programmable apparatus, or other devices to produce a computer-implemented process such that the instructions that execute on the computer or other programmable apparatus provide processes for implementing the functions/acts specified in the flowchart and/or block diagram block or blocks.

In FIG. 1, computer system 101, such as the controller 28 or the analogue control system 200 includes a processor 103 coupled through one or more I/O Interfaces 109 to one or more hardware data storage devices 111 and one or more I/O devices 113 and 115.

Hardware data storage devices 111 may include, but are not limited to, magnetic tape drives, fixed or removable hard disks, optical discs, storage-equipped mobile devices, and solid-state random-access or read-only storage devices. I/O devices may comprise, but are not limited to: input devices 113, such as keyboards, scanners, handheld telecommunications devices, touch-sensitive displays, tablets, biometric readers, joysticks, trackballs, or computer mice; and output devices 115, which may comprise, but are not limited to printers, plotters, tablets, mobile telephones, displays, or sound-producing devices. Data storage devices 111, input devices 113, and output devices 115 may be located either locally or at remote sites from which they are connected to I/O Interface 109 through a network interface.

Processor 103 may also be connected to one or more memory devices 105, which may include, but are not limited to, Dynamic RAM (DRAM), Static RAM (SRAM), Programmable Read-Only Memory (PROM), Field-Programmable Gate Arrays (FPGA), Secure Digital memory cards, SIM cards, or other types of memory devices such as EPROM and EEPROM.

At least one memory device 105 contains stored computer program code 107, which is a computer program that comprises computer-executable instructions. The stored computer program code includes a program that implements a method for the efficient selection of runtime rules for programmable search in accordance with embodiments of the present invention, and may implement other embodiments described in this specification, including the methods illustrated in FIGS. 2-6. The data storage devices 111 may store the computer program code 107. Computer program code 107 stored in the storage devices 111 is configured to be executed by processor 103 via the memory devices 105. Processor 103 executes the stored computer program code 107.

Thus the present invention discloses a process for supporting computer infrastructure, integrating, hosting, maintaining, and deploying computer-readable code into the computer system 101, wherein the code in combination with the computer system 101 is capable of performing a method for the efficient selection of runtime rules for programmable search.

Any of the components of the present invention could be created, integrated, hosted, maintained, deployed, managed, serviced, supported, etc. by a service provider who offers to facilitate a method for the efficient selection of runtime rules for programmable search. Thus the present invention discloses a process for deploying or integrating computing infrastructure, comprising integrating computer-readable code into the computer system 101, wherein the code in combination with the computer system 101 is capable of performing a method for the efficient selection of runtime rules for programmable search.

One or more data storage units 111 (or one or more additional memory devices not shown in FIG. 1) may be used as a computer-readable hardware storage device having a computer-readable program embodied therein and/or having other data stored therein, wherein the computer-readable program comprises stored computer program code 107. Generally, a computer program product (or, alternatively, an article of manufacture) of computer system 101 may comprise said computer-readable hardware storage device.

While it is understood that program code 107 for executing the method for moving a solar panel structure or device may be deployed by manually loading the program code 107 directly into client, server, and proxy computers (not shown) by loading the program code 107 into a computer-readable storage medium (e.g., computer data storage device 111), program code 107 may also be automatically or semi-automatically deployed into computer system 101 by sending program code 107 to a central server (e.g., computer system 101) or to a group of central servers. Program code 107 may then be downloaded into client computers (not shown) that will execute program code 107.

Alternatively, program code 107 may be sent directly to the client computer via e-mail. Program code 107 may then either be detached to a directory on the client computer or loaded into a directory on the client computer by an e-mail option that selects a program that detaches program code 107 into the directory.

Another alternative is to send program code 107 directly to a directory on the client computer hard drive. If proxy servers are configured, the process selects the proxy server code, determines on which computers to place the proxy servers' code, transmits the proxy server code, and then installs the proxy server code on the proxy computer. Program code 107 is then transmitted to the proxy server and stored on the proxy server.

In one embodiment, program code 107 for executing the method for performing a bond transaction is integrated into a client, server and network environment by providing for program code 107 to coexist with software applications (not shown), operating systems (not shown) and network operating systems software (not shown) and then installing program code 107 on the clients and servers in the environment where program code 107 will function.

The first step of the aforementioned integration of code included in program code 107 is to identify any software on the clients and servers, including the network operating system (not shown), where program code 107 will be deployed that are required by program code 107 or that work in conjunction with program code 107. This identified software includes the network operating system, where the network operating system comprises software that enhances a basic operating system by adding networking features. Next, the software applications and version numbers are identified and compared to a list of software applications and correct version numbers that have been tested to work with program code 107. A software application that is missing or that does not match a correct version number is upgraded to the correct version.

A program instruction that passes parameters from program code 107 to a software application is checked to ensure that the instruction's parameter list matches a parameter list required by the program code 107. Conversely, a parameter passed by the software application to program code 107 is checked to ensure that the parameter matches a parameter required by program code 107. The client and server operating systems, including the network operating systems, are identified and compared to a list of operating systems, version numbers, and network software programs that have been tested to work with program code 107. An operating system, version number, or network software program that does not match an entry of the list of tested operating systems and version numbers is upgraded to the listed level on the client computers and upgraded to the listed level on the server computers.

After ensuring that the software, where program code 107 is to be deployed, is at a correct version level that has been tested to work with program code 107, the integration is completed by installing program code 107 on the clients and servers.

Elements of the embodiments have been introduced with either the articles “a” or “an.” The articles are intended to mean that there are one or more of the elements. The terms “including” and “having” and their derivatives are intended to be inclusive such that there may be additional elements other than the elements listed. The conjunction “or” when used with a list of at least two terms is intended to mean any term or combination of terms. The terms “first” and “second” are used to distinguish elements and are not used to denote a particular order.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

1. A solar panel support structure comprising:
a base;
a mounting structure extending from the base;
a frame connected to the mounting structure, the frame configured to receive a solar panel;
a first actuator configured to rotate the frame in a first rotational direction;
a second actuator configured to rotate the frame in a second rotational direction, wherein the second rotational direction is perpendicular to the first rotational direction;
a light sensor system configured to determine the intensity of light coming from each of a north direction, a south direction, an east direction and a west direction; and
a controller configured to receive input from the light sensor system and control the first actuator and the second actuator such that the first actuator and the second actuator position the frame such that the frame is at least one of perpendicular and substantially perpendicular to the sun.

2. The solar panel support structure of claim 1, further comprising an analogue control system configured to detect a day state and a night state, the analogue control system in communication with the controller for communicating to the controller the whether the solar panel support structure resides in the day state or the night state.

3. The solar panel support structure of claim 2, further comprising a display system configured to display at least one of an overcharge protection state, low battery voltage, a charging state, a discharging state, and a power save mode being activated.

4. The solar panel support structure of claim 2, wherein the analogue control system and a portion of the post are each located within the base, wherein the analogue control system includes an upper protruding plane having an LED disposed thereon, and a lower protruding plane having an LDR disposed thereon, wherein the LED directs light at the LDR, wherein the analogue control system further includes a blade attached to the post such that the blade rotates with the post, wherein the blade is configured to block the light from the LED from reaching the LDR when post has been rotated to a predetermined position that corresponds to an end of daylight in a given day.

5. The solar panel support structure of claim 1, wherein the light sensor system further includes a first sensor located within a first opening facing the north direction, a second sensor located within a second opening facing the south direction, a third sensor located within a third opening facing the east direction, and a fourth sensor located within a fourth opening facing the west direction, and wherein the first, second, third and fourth sensors are each npn phototransistors.

6. The solar panel support structure of claim 5, wherein the base is configured to rest on a surface and is heavy enough to support the frame and the solar panel without requiring substantial below ground installation.

7. The solar panel support structure of claim 6, wherein the light sensor system is attached to a top edge of the frame and includes a surface into which the first, second, third and fourth openings are located, wherein the surface is oriented parallel to a plane defined by outer edges of the frame.

8. The solar panel support structure of claim 7, wherein the mounting structure further includes a post extending from the base, and wherein the post is at least one of:
telescopic and includes an extended position and a retracted position in order to move a height of the frame relative to the base; and
sectional such that the post is receptive of additional attachable lengths in order to move the height of the frame relative to the base.

9. The solar panel support structure of claim 8, wherein the first actuator is located within the base and wherein the second actuator is located above the base and extends between the post and the frame, and wherein the first actuator is telescopic and actuated at least one of hydraulically, electrically and pneumatically, and wherein the second actuator is telescopic and actuated at least one of hydraulically, electrically and pneumatically.

10. The solar panel support structure of claim 9, wherein the first actuator is configured to rotate the post with respect to the base when the first actuator is expanded or contracted, and wherein the second actuator is configured to rotate the frame with respect to the post when the second actuator is expanded or contracted.

11. A solar panel device comprising:
a base;
a post extending from the base;
a frame connected to the post;
at least one solar panel attached to the frame;
a first actuator configured to rotate the post with respect to the base;
a second actuator configured to rotate the frame with respect to the post;
a light sensor system including a first sensor located within a first opening facing a north direction, a second sensor located within a second opening facing a south direction, a third sensor located within a third opening facing an east direction, and a fourth sensor located within a fourth opening facing a west direction, wherein the light sensor system is configured to determine the intensity of light coming from each of the north direction, the south direction, the east direction and the west direction; and
a controller configured to receive input from the light sensor system and control the first actuator and the second actuator such that the first actuator and the second actuator position the frame such the solar panel faces a direction that receives a maximum amount of light energy.

12. The solar panel device of claim 11, further comprising an analogue control system configured to detect a day state and a night state, the analogue control system in communication with the controller for communicating to the controller the whether the solar panel support structure resides in the day state or the night state.

13. The solar panel device of claim 12, further comprising a display system configured to display at least one of an overcharge protection state, low battery voltage, a charging state, a discharging state, and a power save mode being activated.

14. The solar panel device of claim 11, wherein the first sensor, the second sensor, the third sensor and the fourth sensor are each npn phototransistors.

15. The solar panel device of claim 14, wherein the base is configured to rest on a surface and is heavy enough to support the frame and the solar panel without requiring substantial below ground installation.

16. The solar panel device of claim 15, wherein the light sensor system is attached to a top edge of the frame and includes a surface into which the first, second, third and fourth openings are located, the surface oriented parallel to a plane defined by outer edges of the frame.

17. The solar panel device of claim 16, wherein the post is telescopic and includes an extended position and a retracted position in order to move a height of the frame relative to the base.

18. The solar panel device of claim 17, wherein the first actuator is located within the base and wherein the second actuator is located above the base and extends between the post and the frame, and wherein the first actuator is telescopic and actuated at least one of hydraulically, electrically and pneumatically, and wherein the second actuator is telescopic and actuated at least one of hydraulically, electrically and pneumatically.

19. The solar panel device of claim 12, wherein the analogue control system includes an upper protruding plane having an LED disposed thereon, and a lower protruding plane having an LDR disposed thereon, wherein the LED directs light at the LDR, wherein the analogue control system further includes a blade attached to the post such that the blade rotates with the post, wherein the blade is configured to block the light from the LED from reaching the LDR when post has been rotated to a predetermined position that corresponds to an end of daylight in a given day.

20. A method comprising:
providing a solar panel support structure including:
a base;
a mounting structure extending from the base;
a frame connected to the mounting structure, the frame configured to receive a solar panel;
a first actuator;
a second actuator;
a light sensor system; and
a controller;
rotating the frame in a first rotational direction with the first actuator;
rotating the frame in a second rotational direction with the second actuator, the second rotational direction being perpendicular to the first rotational direction;
determining, by the light sensor system, the intensity of light coming from each of a north direction, a south direction, an east direction, and a west direction;
receiving, by the controller, input from the light sensor system information pertaining to the intensity of light coming from the north direction, the south direction, the east direction, and the west direction;
controlling, by the controller, the first actuator and the second actuator; and
positioning, by the controller, the first actuator, and the second actuator, the frame such that the frame is at least one of perpendicular and substantially perpendicular to the sun.
